(19) United States
(12) Patent Application Publication
(10) Pub. No.: US 2024/0422701 A1
(43) Pub. Date: Dec. 19, 2024

(54) SYSTEM AND METHOD FOR ADJUSTING FEEDBACK RECEIVER (FBRX) GAIN SWITCH POINT

(71) Applicant: QUALCOMM INCORPORATED, SAN DIEGO, CA (US)

(72) Inventors: Mahabrata MUKHERJEE, Hyderabad (IN); Shobhit SRIVASTAVA, San Diego, CA (US); Tarandeep VIRK, San Diego, CA (US)

(21) Appl. No.: 18/336,414

(22) Filed: Jun. 16, 2023

(51) Int. Cl. H04W 52/52; H04W 52/24

(52) U.S. Cl. CPC H04W 52/52; H04W 52/241

(57) ABSTRACT

A system for adjusting feedback receiver gain including a power amplifier configured to generate a transmit signal, a feedback receiver configured to receive a portion of the transmit signal, the feedback receiver having a gain element and an analog-to-digital converter (ADC), and a processor and a memory operably coupled to the gain element; wherein the processor and memory are configured to select an adjusted gain switch point for the gain element based on a difference between a measured ADC input power and an expected ADC input power.

### FIELD

The present disclosure relates generally to electronics, and more specifically to transmitters and receivers in a transceiver.

### BACKGROUND

Wireless communication devices and technologies are becoming ever more prevalent, as are communication devices that operate at various different frequencies. Wireless communication devices generally transmit and/or receive communication signals. In a radio frequency (RF) transceiver, a communication signal is typically amplified and transmitted by a transmit section and a received communication signal is amplified and processed by a receive section. A transceiver for communication in 5G and 6G applications may communicate using various frequencies, including for example millimeter wave (mmW) frequency signals and/or sub-THz frequencies and may use what is referred to as a zero intermediate frequency (ZIF) architecture or a low-IF architecture in some implementations.

In some transceivers it is common to sample a transmit signal using a receiver associated with the transceiver. In some applications, such a receiver may be referred to as a feedback receiver (FBRx). A feedback receiver is typically used for transmit (Tx) power control, antenna impedance/coupling measurement, antenna tuning, applying predistortion, etc. In some applications, a feedback receiver is provided with the output of a power amplifier in the transceiver using a coupler. Such a transmit signal is “fed back” to the feedback receiver via a coupler so that the feedback receiver and other signal processing elements may analyze the transmit signal to provide transmit power output control and other functions.

A feedback receiver should be capable of processing signals at a wide range of power levels and varied or varying coupler efficiency. However, such variations in the output power and coupler efficiency may result in significant signal power variations provided to the feedback receiver and subsequent processing elements. Therefore, it would be desirable to have a way to compensate for such power and coupler efficiency variations.

### SUMMARY

Various implementations of systems, methods and devices within the scope of the appended claims each have several aspects, no single one of which is solely responsible for the desirable attributes described herein. Without limiting the scope of the appended claims, some prominent features are described herein.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

One aspect of the disclosure provides a system for adjusting feedback receiver gain including a power amplifier configured to generate a transmit signal, a feedback receiver configured to receive a portion of the transmit signal, the feedback receiver having a gain element and an analog-to-digital converter (ADC), and a processor and a memory operably coupled to the gain element; wherein the processor and memory are configured to select an adjusted gain switch point for the gain element based on a difference between a measured ADC input power and an expected ADC input power.

Another aspect of the disclosure provides a method for adjusting gain including determining an expected analog-to-digital converter (ADC) input power, measuring an actual ADC input power, determining a difference (A) between the actual ADC input power and the expected ADC input power, and adjusting a gain switch point based on the difference (A).

Another aspect of the disclosure provides a device for adjusting gain including means for determining an expected analog-to-digital converter (ADC) input power, means for measuring an actual ADC input power, means for determining a difference (Δ) between the actual ADC input power and the expected ADC input power, and means for adjusting a gain switch point based on the difference (A).

Another aspect of the disclosure provides a communication device including a transmitter comprising a power amplifier configured to generate a transmit signal and a power coupler, a feedback receiver comprising a gain element and an analog-to-digital converter (ADC), the power coupler configured to provide a portion of the transmit signal to the feedback receiver, and a processor and a memory operably coupled to the gain element; wherein the processor and memory are configured to select gain switch points for the gain element based on a difference between a measured actual ADC input power of the ADC and an expected ADC input power of the ADC.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a diagram showing a wireless device communicating with a wireless communication system.

FIG. 2A is a block diagram showing a wireless device in which exemplary techniques of the present disclosure may be implemented.

FIG. 2B is a block diagram showing a wireless device in which exemplary techniques of the present disclosure may be implemented.

FIG. 2C is a block diagram showing a wireless device in which exemplary techniques of the present disclosure may be implemented.

FIG. 3 is a block diagram of a portion of a transceiver in accordance with an exemplary embodiment.

FIG. 4 is a graph showing the effect of exemplary gain variations on ADC saturation and on signal-to-noise ratio SNR (or carrier-to-noise ratio (CNR)) at the input to the ADC of FIG. 3.

FIG. 5 is a graph showing the effect of exemplary gain variations on ADC saturation and on signal-to-noise ratio SNR (or carrier-to-noise ratio (CNR)) at the input to the ADC after switch point adjustment by the system and method for adjusting feedback receiver (FBRx) gain switch points.

FIG. 6A is a graph showing an exemplary maximum gain trace in a communication system that does not have the system and method for adjusting feedback receiver (FBRx) gain switch points.

FIG. 6B shows a table showing proposed gain switch points corresponding to the worst case (+) gain condition shown in FIG. 6A.

FIG. 7A is a graph showing an exemplary maximum gain trace in a communication system having the system and method for adjusting feedback receiver (FBRx) gain switch points.

FIG. 7B shows a table showing proposed gain switch points corresponding to the worst case maximum (+) gain condition shown using trace of FIG. 7A.

FIG. 8A is a graph showing an exemplary minimum gain trace in a communication system that does not have the system and method for adjusting feedback receiver (FBRx) gain switch points.

FIG. 8B shows a table showing proposed gain switch points corresponding to the worst case minimum (−) gain condition shown using trace of FIG. 8A.

FIG. 9A is a graph showing an exemplary minimum gain trace in a communication system having the system and method for adjusting feedback receiver (FBRx) gain switch points.

FIG. 9B shows a table showing proposed gain switch points corresponding to the worst case minimum (−) gain condition shown using trace of FIG. 9A.

FIG. 10 is a flow chart describing an example of the operation of a method for adjusting FBRx gain switch points.

FIG. 11 is a functional block diagram of an apparatus for adjusting FBRx gain switch points.

### DETAILED DESCRIPTION

The word “exemplary” is used herein to mean “serving as an example, instance, or illustration.” Any aspect described herein as “exemplary” is not necessarily to be construed as preferred or advantageous over other aspects.

In accordance with an exemplary embodiment, a system and method for adjusting feedback receiver (FBRx) gain switch points is disclosed.

In accordance with an exemplary embodiment, a system and method for adjusting feedback receiver (FBRx) gain switch points may be used to control an amount of transmit power provided to an analog to digital converter (ADC) in a feedback receiver to minimize ADC saturation and maximize signal-to-noise ratio (SNR).

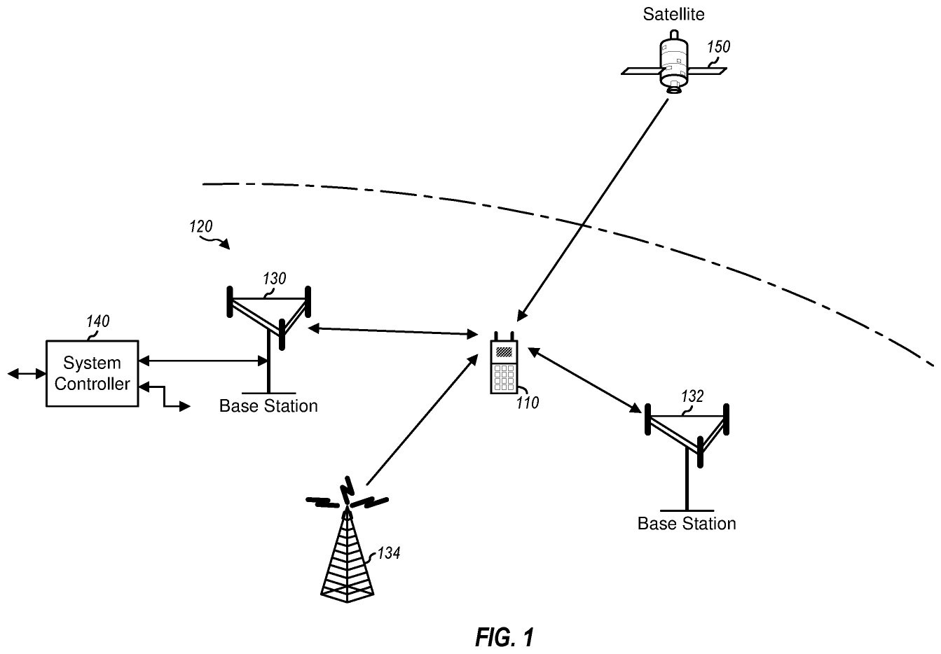

FIG. 1 is a diagram showing a wireless device 110 communicating with a wireless communication system 120. The wireless communication system 120 may be a Long Term Evolution (LTE) system, a Code Division Multiple Access (CDMA) system, a Global System for Mobile Communications (GSM) system, a wireless local area network (WLAN) system, a 5G NR (new radio) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a tablet, a cordless phone, a medical device, an automobile, a device configured to connect to one or more other devices (for example through the internet of things), a wireless local loop (WLL) station, a Bluetooth device, etc. Wireless device 110 may communicate with wireless communication system 120. Wireless device 110 may also receive signals from broadcast stations (e.g., a broadcast station 134) and/or may communicate with satellites (e.g., a satellite 150 in one or more global navigation satellite systems (GNSS)), or a satellite that can receive signals from the wireless device 110, etc). Wireless device 110 may support one or more radio technologies for wireless communication such as LTE, WCDMA, CDMA 1X, EVDO, TD-SCDMA, GSM, 802.11, 802.15, 5G, Sub6 5G, 6G, UWB, etc.

Wireless device 110 may support carrier aggregation, for example as described in one or more LTE or 5G standards. In some embodiments, a single stream of data is transmitted over multiple carriers using carrier aggregation, for example as opposed to separate carriers being used for respective data streams. Wireless device 110 may be able to operate in a variety of communication bands including, for example, those communication bands used by LTE, WiFi, 5G or other communication bands, over a wide range of frequencies. Wireless device 110 may also be capable of communicating directly with other wireless devices without communicating through a network.

In general, carrier aggregation (CA) may be categorized into two types-intra-band CA and inter-band CA. Intra-band CA refers to operation on multiple carriers within the same band. Inter-band CA refers to operation on multiple carriers in different bands.

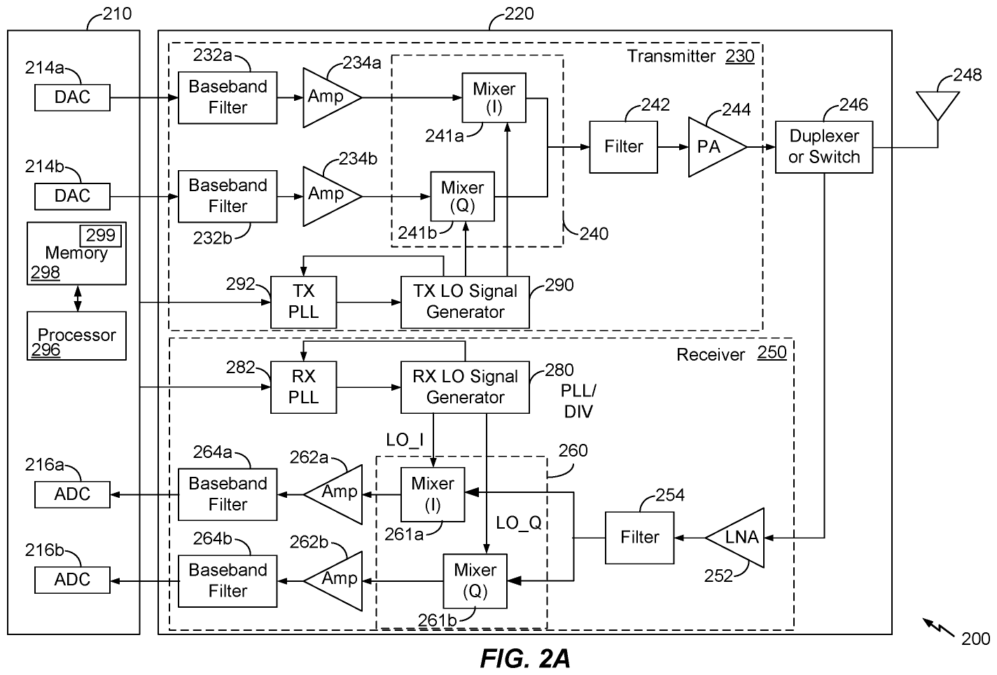

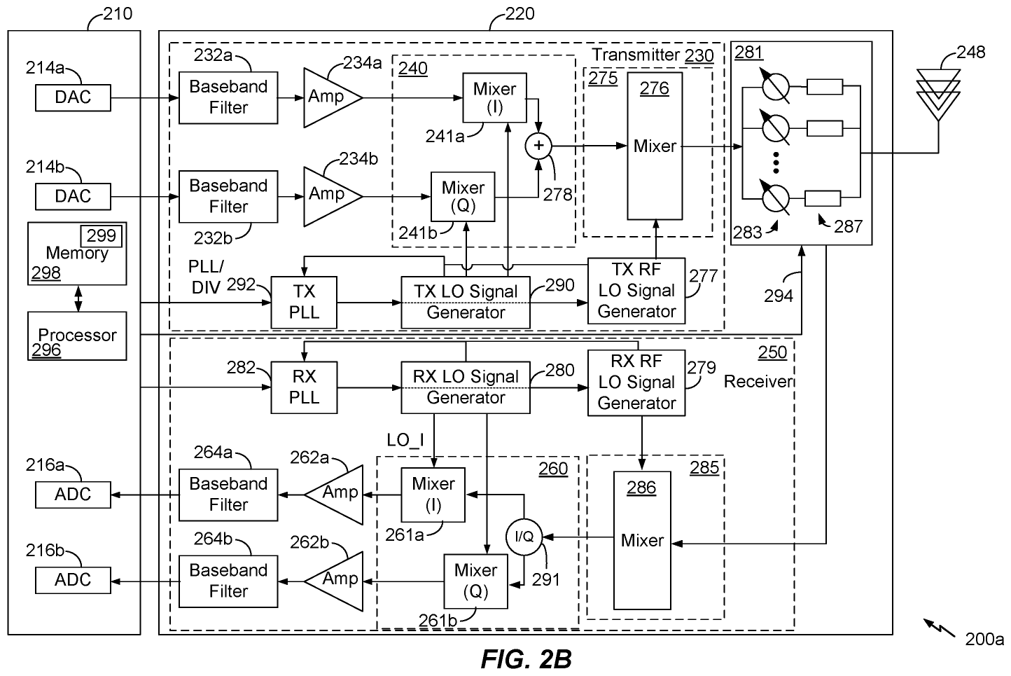

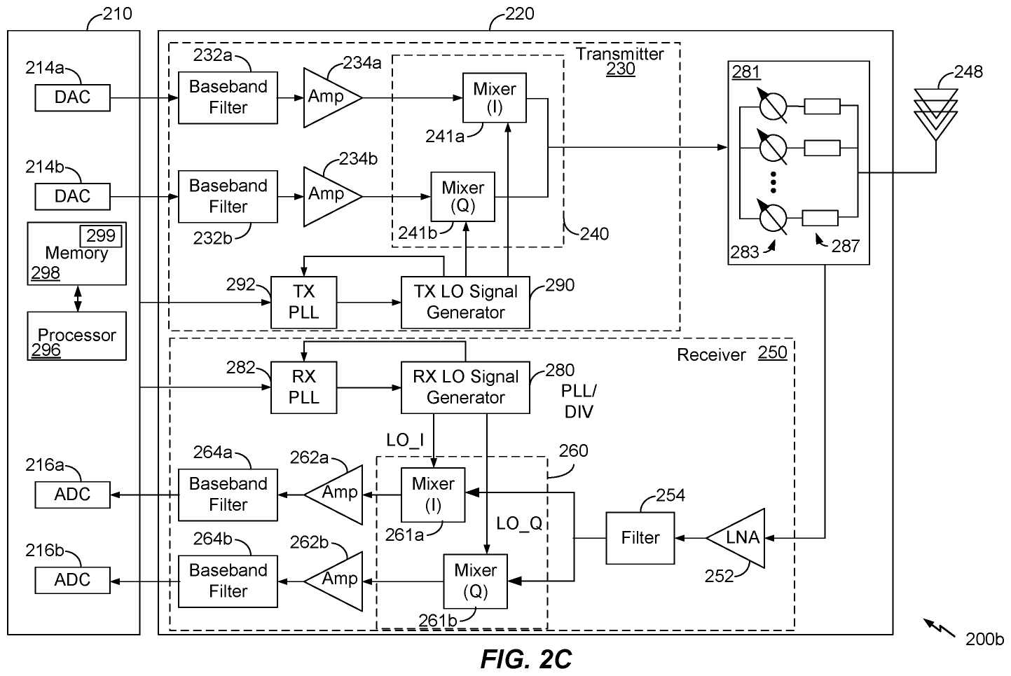

FIG. 2A is a block diagram showing a wireless device 200 in which exemplary techniques of the present disclosure may be implemented. The wireless device 200 may, for example, be an embodiment of the wireless device 110 illustrated in FIG. 1.

FIG. 2A shows an example of a transceiver 220 having a transmitter 230 and a receiver 250. In general, the conditioning of the signals in the transmitter 230 and the receiver 250 may be performed by one or more stages of amplifier, filter, upconverter, downconverter, etc. These circuit blocks may be arranged differently from the configuration shown in FIG. 2A. Furthermore, other circuit blocks not shown in FIG. 2A may also be used to condition the signals in the transmitter 230 and receiver 250. Unless otherwise noted, any signal in FIG. 2A, or any other figure in the drawings, may be either single-ended or differential. Some circuit blocks in FIG. 2A may also be omitted.

In the example shown in FIG. 2A, wireless device 200 generally comprises the transceiver 220 and a data processor 210. The data processor 210 may include a processor 296 operatively coupled to a memory 298. The memory 298 may be configured to store data and program codes shown generally using reference numeral 299, and may generally comprise analog and/or digital processing components. The processor 296 and the memory 298 may cooperate to control, configure, program, or otherwise fully or partially control some or all of the operation of the embodiments of the feedback receiver (FBRx) gain switch point adjustment circuit described herein.

The transceiver 220 includes a transmitter 230 and a receiver 250 that support bi-directional communication. In general, wireless device 200 may include any number of transmitters and/or receivers for any number of communication systems and frequency bands. All or a portion of the transceiver 220 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the example shown in FIG. 2A, transmitter 230 and receiver 250 are implemented with the direct-conversion architecture.

In the transmit path, the data processor 210 processes data to be transmitted and provides in-phase (I) and quadrature (Q) analog output signals to the transmitter 230. In an exemplary embodiment, the data processor 210 includes digital-to-analog-converters (DAC's) 214a and 214b for converting digital signals generated by the data processor 210 into the I and Q analog output signals, e.g., I and Q output currents, for further processing. In other embodiments, the DACs 214a and 214b are included in the transceiver 220 and the data processor 210 provides data (e.g., for I and Q) to the transceiver 220 digitally.

Within the transmitter 230, baseband (e.g., lowpass) filters 232a and 232b filter the I and Q analog transmit signals, respectively, to remove undesired images caused by the prior digital-to-analog conversion. Amplifiers (Amp) 234a and 234b amplify the signals from baseband filters 232a and 232b, respectively, and provide I and Q baseband signals. An upconverter 240 having upconversion mixers 241a and 241b upconverts the I and Q baseband signals with I and Q transmit (TX) local oscillator (LO) signals from a TX LO signal generator 290 and provides an upconverted signal. A filter 242 filters the upconverted signal to remove undesired images caused by the frequency upconversion as well as noise in a receive frequency band. A power amplifier (PA) 244 amplifies the signal from filter 242 to obtain the desired output power level and provides a transmit RF signal. The transmit RF signal may be routed through a duplexer or switch 246 and transmitted via an antenna 248. While examples discussed herein utilize I and Q signals, those of skill in the art will understand that components of the transceiver may be configured to utilize polar modulation.

In the receive path, antenna 248 receives communication signals and provides a received RF signal, which may be routed through duplexer or switch 246 and provided to a low noise amplifier (LNA) 252. The duplexer 246 is designed to operate with a specific RX-to-TX duplexer frequency separation, such that RX signals are isolated from TX signals. The received RF signal is amplified by LNA 252 and filtered by a filter 254 to obtain a desired RF input signal.

Downconversion mixers 261a and 261b in a downconverter 260 mix the output of filter 254 with I and Q receive (RX) LO signals (i.e., LO_I and LO_Q) from an RX LO signal generator 280 to generate I and Q baseband signals. The I and Q baseband signals are amplified by amplifiers 262a and 262b and further filtered by baseband (e.g., lowpass) filters 264a and 264b to obtain I and Q analog input signals, which are provided to data processor 210. In the exemplary embodiment shown, the data processor 210 includes analog-to-digital-converters (ADC's) 216a and 216b for converting the analog input signals into digital signals to be further processed by the data processor 210. In some embodiments, the ADCs 216a and 216b are included in the transceiver 220 and provide data to the data processor 210 digitally.

In FIG. 2A, TX LO signal generator 290 generates the I and Q TX LO signals used for frequency upconversion, while RX LO signal generator 280 generates the I and Q RX LO signals used for frequency downconversion. Each LO signal is a periodic signal with a particular fundamental frequency. A phase locked loop (PLL) 292 receives timing information from data processor 210 and generates a control signal used to adjust the frequency and/or phase of the TX LO signals from LO signal generator 290. Similarly, a PLL 282 receives timing information from data processor 210 and generates a control signal used to adjust the frequency and/or phase of the RX LO signals from LO signal generator 280.

Wireless device 200 may support CA and may (i) receive multiple downlink signals transmitted by one or more cells on multiple downlink carriers at different frequencies and/or (ii) transmit multiple uplink signals to one or more cells on multiple uplink carriers. Those of skill in the art will understand, however, that aspects described herein may be implemented in systems, devices, and/or architectures that do not support carrier aggregation.

Certain components of the transceiver 220 are functionally illustrated in FIG. 2A, and the configuration illustrated therein may or may not be representative of a physical device configuration in certain implementations. For example, as described above, transceiver 220 may be implemented in various integrated circuits (ICs), RF ICs (RFICs), mixed-signal ICs, etc. In some embodiments, the transceiver 220 is implemented on a substrate or board such as a printed circuit board (PCB) having various modules, chips, and/or components. For example, the power amplifier 244, the filter 242, and the duplexer 246 may be implemented in separate modules or as discrete components, while the remaining components illustrated in the transceiver 220 may be implemented in a single transceiver chip.

The power amplifier 244 may comprise one or more stages comprising, for example, driver stages, power amplifier stages, or other components, that can be configured to amplify a communication signal on one or more frequencies, in one or more frequency bands, and at one or more power levels. Depending on various factors, the power amplifier 244 can be configured to operate using one or more driver stages, one or more power amplifier stages, one or more impedance matching networks, and can be configured to provide good linearity, efficiency, or a combination of good linearity and efficiency.

In an exemplary embodiment in a super-heterodyne architecture, the PA 244 and LNA 252 (and filter 242 and filter 254 in some examples) may be implemented separately from other components in the transmitter 230 and receiver 250, for example on a millimeter wave integrated circuit. An example super-heterodyne architecture is illustrated in FIG. 2B.

FIG. 2B is a block diagram showing a wireless device in which exemplary techniques of the present disclosure may be implemented. Certain components, for example which may be indicated by identical reference numerals, of the wireless device 200a in FIG. 2B may be configured similarly to those in the wireless device 200 shown in FIG. 2A and the description of identically numbered items in FIG. 2B will not be repeated.

The wireless device 200a is an example of a heterodyne (or superheterodyne) architecture in which the upconverter 240 and the downconverter 260 are configured to process a communication signal between baseband and an intermediate frequency (IF). The IF signal may be a low IF (LIF) signal, or a zero (or near zero) IF (ZIF) signal. For example, the upconverter 240 may be configured to provide an IF signal to an upconverter 275. In an exemplary embodiment, the upconverter 275 may comprise an upconversion mixer 276. The summing function 278, which may be part of the upconverter 240 combines the I and the Q outputs of the upconverter 240 and provides a non-quadrature signal to the mixer 276. The non-quadrature signal may be single ended or differential. The mixer 276 is configured to receive the IF signal from the upconverter 240 and TX RF LO signals from a TX RF LO signal generator 277, and provide an upconverted RF signal to phase shift circuitry 281. While PLL 292 is illustrated in FIG. 2B as being shared by the signal generators 290, 277, a respective PLL for each signal generator may be implemented. In an exemplary embodiment, the phase shift circuitry 281 may be part of or may be located on a millimeter wave integrated circuit (mmW-IC).

In an exemplary embodiment, components in the phase shift circuitry 281 may comprise one or more adjustable or variable phased array elements, and may receive one or more control signals from the data processor 210 over connection 294 and operate the adjustable or variable phased array elements based on the received control signals.

In an exemplary embodiment, the phase shift circuitry 281 comprises phase shifters 283 and phased array elements 287. Although three phase shifters 283 and three phased array elements 287 are shown for ease of illustration, the phase shift circuitry 281 may comprise more or fewer phase shifters 283 and phased array elements 287. For example, one or two arrays of four or five antennas and corresponding phase shifters/phased array elements may be implemented.

Each phase shifter 283 may be configured to receive the RF transmit signal from the upconverter 275, alter the phase by an amount, and provide the RF signal to a respective phased array element 287. Each phased array element 287 may comprise transmit and receive circuitry including one or more filters, amplifiers, driver amplifiers, and/or power amplifiers. In some embodiments, the phase shifters 283 may be incorporated within respective phased array elements 287.

The output of the phase shift circuitry 281 is provided to an antenna array 248. In an exemplary embodiment, the antenna array 248 comprises a number of antennas that typically correspond to the number of phase shifters 283 and phased array elements 287, for example such that each antenna element is coupled to a respective phased array element 287. In an exemplary embodiment, the phase shift circuitry 281 and the antenna array 248 may be referred to as a phased array.

In a receive direction, an output of the phase shift circuitry 281 is provided to a downconverter 285. In an exemplary embodiment, the downconverter 285 may comprise a downconversion mixer 286. In an exemplary embodiment, the mixer 286 downconverts the receive RF signal provided by the phase shift circuitry 281 to an IF signal according to RX RF LO signals provided by an RX RF LO signal generator 279. An I/Q generation function 291 in the downconverter 260 receives the IF signal from the mixer 286 and generates I and Q signals for the downconverter 260, which downconverts the IF signals to baseband, as described above. While PLL 282 is illustrated in FIG. 2B as being shared by the signal generators 280, 279, a respective PLL for each signal generator may be implemented.

In some embodiments, the upconverter 275, downconverter 285, and the phase shift circuitry 281 are implemented on a common IC. In some embodiments, the summing function 278 and the I/Q generation function 291 are implemented separate from the mixers 276 and 286 such that the mixers 276, 286 and the phase shift circuitry 281 are implemented on the common IC, but the summing function 278 and I/Q generation function 291 are not (e.g., the summing function 278 and I/Q generation function 291 are implemented in another IC coupled to the IC having the mixers 276, 286). In some embodiments, the LO signal generators 277, 279 are included in the common IC. In some embodiments in which phase shift circuitry is implemented on a common IC with 276, 286, 277, 278, 279, and/or 291, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect or both are mounted to a substrate. For example, components of the antenna array 248 may be implemented on a substrate and coupled to an integrated circuit implementing the phase shift circuitry 281 via a flexible printed circuit or the integrated circuit may be mounted to an opposite side of the substrate. In some embodiments, both the architecture illustrated in FIG. 2A and the architecture illustrated in FIG. 2B are implemented in the same device. For example, a wireless device 110 or 200 may be configured to communicate with signals having a frequency below about 20 GHz using the architecture illustrated in FIG. 2A and to communicate with signals having a frequency above about 20 GHz using the architecture illustrated in FIG. 2B. In devices in which both architectures are implemented, one or more components of FIGS. 2A and 2B that are identically numbered may be shared between the two architectures. For example, both signals that have been downconverted directly to baseband from RF and signals that have been downconverted from RF to baseband via an IF stage may be filtered by the same baseband filter 264. In other embodiments, a first version of the filter 264 is included in the portion of the device which implements the architecture of FIG. 2A and a second version of the filter 264 is included in the portion of the device which implements the architecture of FIG. 2B. While certain example frequencies are described herein, other implementations are possible. For example, signals having a frequency above about 20 GHz (e.g., having a mmW frequency) may be transmitted and/or received using a direct conversion architecture. In such embodiments, for example, a phased array may be implemented in the direct conversion architecture.

FIG. 2C is a block diagram showing a wireless device in which exemplary techniques of the present disclosure may be implemented. Certain components, for example which may be indicated by identical reference numerals, of the wireless device 200b in FIG. 2C may be configured similarly to those in the wireless device 200 shown in FIG. 2A and/or the wireless device 200a shown in FIG. 2B and the description of identically numbered items in FIG. 2C will not be repeated.

The wireless device 200b in FIG. 2C incorporates the phase shift circuitry 281 (of FIG. 2B) in a direct conversion architecture, where mmW transmission signals are upconverted and downconverted between baseband and RF without the use of intermediate frequency (IF) signal conversion. For example, the LO signals in the architecture of FIG. 2C may comprise signals at frequencies of tens of GHz.

In some embodiments, the upconverter 240, downconverter 260, and the phase shift circuitry 281 are implemented on a common IC. In some embodiments, the LO signal generators 280, 290 are included in the common IC. In some embodiments, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect or both are mounted to a substrate. For example, components of the antenna array 248 may be implemented on a substrate and coupled to an integrated circuit implementing the phase shift circuitry 281 via a flexible printed circuit or the integrated circuit may be mounted to an opposite side of the substrate.

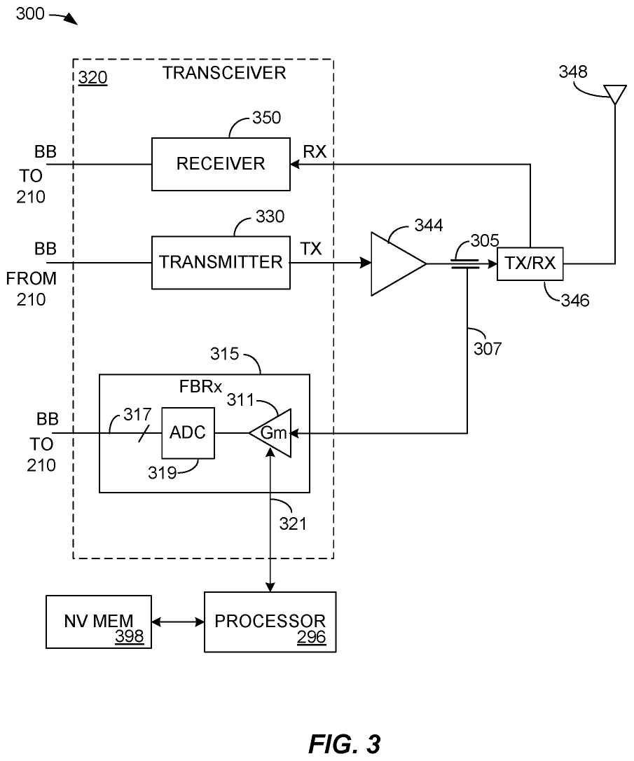

FIG. 3 is a block diagram 300 of a portion of a transceiver in accordance with an exemplary embodiment. In an exemplary embodiment, a transceiver 320 may be an exemplary embodiment of the transceiver 220 of FIG. 2A, 2B or 2C.

The transceiver 320 may include a transmitter 330 and a receiver 350. The transmitter 330 may be configured to receive a baseband (BB) transmit signal from the data processor 210 (FIG. 2A) and may provide a transmit signal to a power amplifier (PA) 344. The PA may be connected to a duplexer or switch 346. The PA 344 may be an example of the power amplifier 244 of FIG. 2A and the duplexer or switch 346 may be an example of the duplexer or switch 246 of FIG. 2A. The duplexer or switch 346 may be connected to an antenna 348 or to an array of antenna elements.

The receiver 350 may be connected to the duplexer or switch 346 and may be configured to process a receive communication signal and provide a digital baseband (BB) output to the data processor 210 (FIG. 2A, 2B, 2C).

In an exemplary embodiment, the transceiver 320 may include a feedback receiver (FBRx) 315. In an exemplary embodiment, the FBRx 315 may be connected to the output of the PA 344 using a coupler 305. The coupler 305 may be configured to provide a portion of the transmit signal from the output of the PA 344 to the input of the FBRx 315 over connection 307 (some other techniques may also be used to provide a portion of the transmit signal to the input of the FBRx 315).

In an exemplary embodiment, the FBRx 315 includes a gain element (Gm stage) 311 and an analog-to-digital converter (ADC). The FBRx 315 may also include other signal processing elements, such as a downconverter, filter, and other elements that are omitted for ease of illustration. The ADC 319 in the FBRx 315 is configured to provide a baseband (BB) signal to the data processor 210 (FIG. 2A, 2B, 2C) over connection 317. In an exemplary embodiment, the gain element 311 (e.g., that could be or be part of an amplifier such as a low noise amplifier) may be operably coupled to the processor 296 (FIG. 2A, 2B, 2C) and a memory 398 over connection 321. In an exemplary embodiment, the memory 398 may be a non-volatile random access memory (NV-RAM), and may be part of the memory 298 of FIG. 2A, 2B or 2C).

In an exemplary embodiment, the gain element 311 may be calibrated and controlled to provide a dynamically variable power level to the input of the ADC 319 responsive to the power output of the PA 344 and the coupling efficiency of the coupler 305.

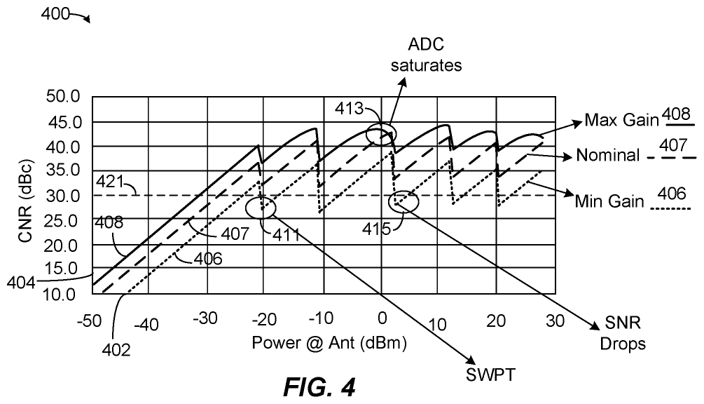

FIG. 4 is a graph 400 showing the effect of exemplary gain variations on ADC saturation and on signal-to-noise ratio SNR (or carrier-to-noise ratio (CNR)) at the input to the ADC 319 of FIG. 3. The graph 400 includes a horizontal axis 402 showing antenna power (Power @ Ant) in dBm, and a vertical axis 404 showing carrier-to-noise ratio (CNR) in dBc.

The graph 400 includes a trace 406 corresponding to minimum gain, a trace 407 corresponding to nominal gain and a trace 408 corresponding to maximum gain.

In an exemplary embodiment, a switch point 411 is shown for example in the minimum gain trace 406. A line 421 drawn at a CNR of approximately 30 dBc illustrates an exemplary CNR threshold below which it is desirable to prevent antenna power from dropping. Each trace 406, 407 and 408 includes gain switch points at intervals that are designed to maintain the input to the ADC 319 (FIG. 3) above a threshold of approximately 30 dBc, shown by line 421, and below a level at which ADC saturation occurs. ADC saturation generally occurs when a power level of a signal that is input to the ADC exceeds a threshold at which the ADC can convert the input signal from analog to digital without errors that exceed a certain threshold.

In an exemplary embodiment, a portion 413 of the maximum gain trace 408 illustrates a condition where the antenna power causes saturation at the input of the ADC 319 (FIG. 3). In an exemplary embodiment, a portion 415 of the minimum gain trace 406 illustrates a condition where the antenna power causes a drop in CNR below the threshold 421 at the input of the ADC 319 (FIG. 3). In an exemplary embodiment, the nominal gain trace 407 illustrates a gain trace having switch points that prevent both ADC saturation and a reduction in CNR.

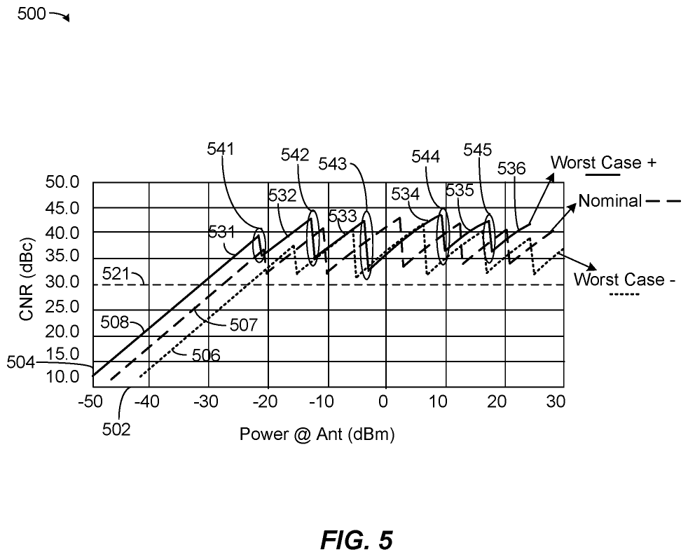

FIG. 5 is a graph 500 showing the effect of exemplary gain variations on ADC saturation and on signal-to-noise ratio SNR (or carrier-to-noise ratio (CNR)) at the input to the ADC 319 (FIG. 3) after switch point adjustment by the system and method for adjusting feedback receiver (FBRx) gain switch points. The graph 500 includes a horizontal axis 502 showing antenna power (Power @ Ant) in dBm, and a vertical axis 504 showing carrier-to-noise ratio (CNR) in dBc.

The graph 500 includes a trace 506 corresponding to a worst case (−) gain condition, a trace 507 corresponding to nominal gain condition and a trace 508 corresponding to a worst case (+) gain condition. In an exemplary embodiment, the worst case (−) gain condition trace 506 shows a case with minimal gain and possible maximum loss from the coupler 305 (FIG. 3); this corresponds to the likelihood of an SNR that drops below a minimum level (such as, for example, a CNR of 30 dBc or less). In an exemplary embodiment, the worst case (+) gain condition trace 508 shows a case with maximum gain and possibly minimum loss from the coupler 305 (FIG. 3). This gain arrangement corresponds to a likelihood of ADC saturation under certain conditions. Using the worst case (+) gain condition trace 508 as an example, the portion 531 may correspond to a gain state of GS0; the portion 532 may correspond to a gain state of GS1; the portion 533 may correspond to a gain state of GS2; the portion 534 may correspond to a gain state of GS3; the portion 535 may correspond to a gain state of GS4; and portion 536 may correspond to a gain state of GS5. Each of the traces 506 and 507 also have portions that correspond to the gain states GS0 through GS5 in this example, but are omitted for ease of illustration. The region between the portion 531 and the portion 532 represents a gain switch point. For example, the region 541 between the portion 531 and the portion 532 may represent a change (switch point) from gain state GS0 to gain state GS1. Similarly, the region 542 between the portion 532 and the portion 533 may represent a change (switch point) from gain state GS1 to gain state GS2; the region 543 between the portion 533 and the portion 534 may represent a change (switch point) from gain state GS2 to gain state GS3; the region 544 between the portion 534 and the portion 535 may represent a change (switch point) from gain state GS3 to gain state GS4; and the region 545 between the portion 535 and the portion 536 may represent a change (switch point) from gain state GS4 to gain state GS5. The traces 506 and 507 also have portions and regions that correspond to the gain states GS0 through GS5 in this example, but are omitted from FIG. 5 for case of illustration.

A line 521 drawn at a CNR threshold of 30 dBc illustrates an exemplary CNR below which it is desirable to prevent antenna power from dropping.

In an exemplary embodiment, each of the traces 506, 507 and 508 include switch points that are designed to prevent both ADC saturation and maintain a minimum SNR for input to the ADC. In an exemplary embodiment, the FBRx 315 and the processor 296 may be configured to analyze a transmit signal provided by the coupler 305 to the gain element 311 and in response adjust the gain switch points of the gain element 311 based on the analyzed transmit signal so that saturation of the ADC 319 is avoided and so that a minimum SNR for input to the ADC 319 is maintained.

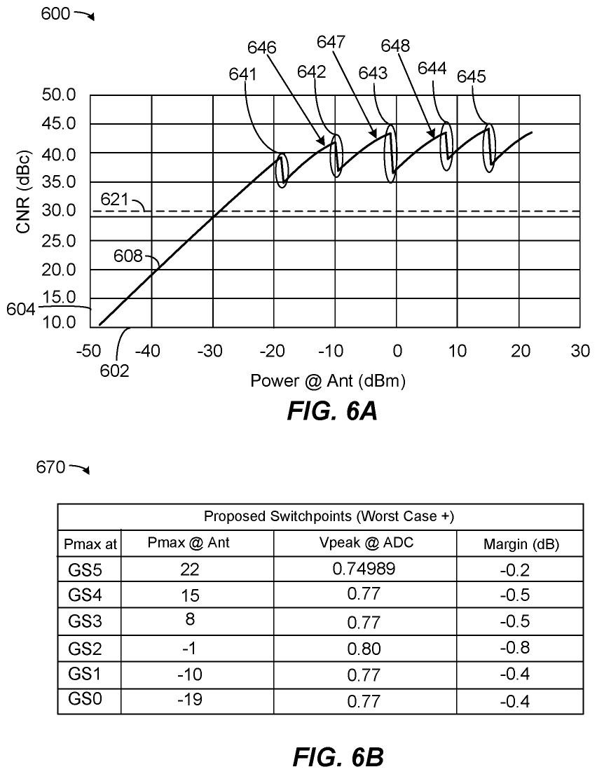

FIG. 6A is a graph 600 showing an exemplary maximum gain trace in a communication system that does not have the system and method for adjusting feedback receiver (FBRx) gain switch points. The graph 600 includes a horizontal axis 602 showing antenna power (Power @ Ant) in dBm, and a vertical axis 604 showing carrier-to-noise ratio (CNR) in dBc.

In an exemplary embodiment, a variable α refers to excess coupling factor related to the coupler 305 (FIG. 3), a variable β refers to excess FBRx gain (e.g., from the gain element 311 of FIG. 3), a variable γ refers to excess gain with temperature variation (e.g., from the NV RAM 398 of FIG. 3) and a variable Δ=β−α.

The graph 600 includes a trace 608 corresponding to a worst case maximum (+) gain condition. In an exemplary embodiment, the worst case maximum (+) gain condition assumes a 3 dB higher than nominal gain and a 3 dB lower than nominal coupling factor such that α is −3 dB; β is 3 dB and Δ=β−α=6 dB.

The trace 608 includes gain switch points 641, 642, 643, 644 and 645. The trace 608 also includes portions that show ADC saturation due to the high gain. For example, portions 646, 647 and 648 of the trace 608 indicate periods of ADC saturation due to excess signal strength. Moreover, the trace 608 shows at least approximately 5 dBc of CNR headroom above the line 621 drawn at a CNR of 30 dBc. The trace 608 shows a condition where the ADC 319 (FIG. 3) may saturate due to excessive signal strength at least at portions 646, 647 and 648.

FIG. 6B shows a table 670 showing proposed gain switch points corresponding to the worst case (+) gain condition shown using trace 608 of FIG. 6A. The table 670 shows a column showing maximum power (Pmax) at gain states GS0, GS1, GS2, GS3, GS4 and GS5; a column showing maximum power at the antenna (Pmax @ Ant), a column showing peak voltage at the input of the ADC (Vpeak @ ADC); and a column showing margin (in dB) for ADC saturation. The margin (in dB) for ADC saturation refers to the margin before ADC saturation where a negative value indicates that the ADC 319 (FIG. 3) has entered saturation.

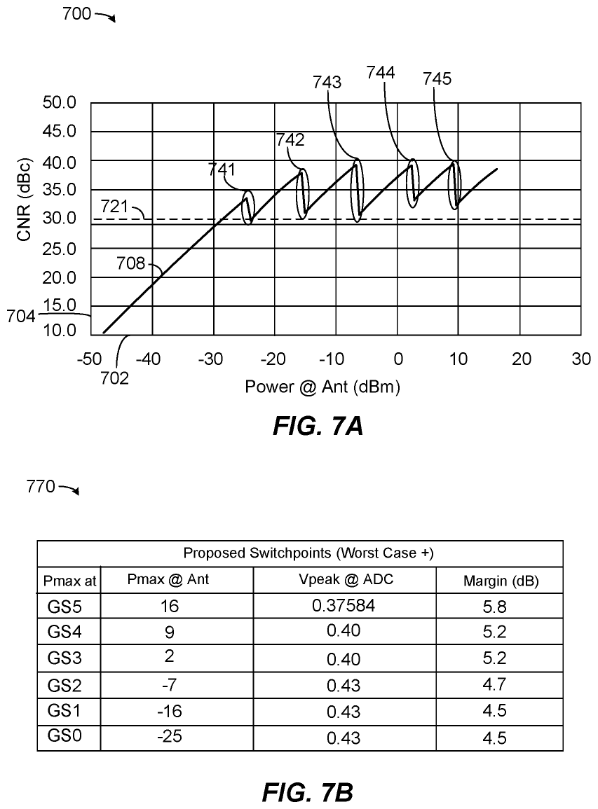

FIG. 7A is a graph 700 showing an exemplary maximum gain trace in a communication system having the system and method for adjusting feedback receiver (FBRx) gain switch points. The graph 700 includes a horizontal axis 702 showing antenna power (Power @ Ant) in dBm, and a vertical axis 704 showing carrier-to-noise ratio (CNR) in dBc.

The graph 700 includes a trace 708 corresponding to a worst case (+) gain condition. The trace 708 includes gain switch points 741, 742, 743, 744 and 745. The trace 708 shows an overall CNR for each gain state that is lower than the overall CNR for each corresponding gain state shown in FIG. 6A for the trace 608. In an exemplary embodiment, the gain switch points 741, 742, 743, 744 and 745 are modified from the gain switch points 641, 642, 643, 644 and 645 shown in FIG. 6A and FIG. 6B such that the trace 708 has a lower likelihood of saturating the ADC 319 (FIG. 3), while still maintaining a CNR higher than 30 dBc for each gain state. For example, the FBRx 315 and the processor 296 may be configured to analyze a transmit signal provided by the coupler 305 to the gain element 311 and in response adjust the gain switch points of the gain element 311 based on the analyzed transmit signal so that saturation of the ADC 319 is avoided and so that α minimum SNR for input to the ADC 319 is maintained.

FIG. 7B shows a table 770 showing proposed gain switch points corresponding to the worst case (+) gain condition shown using trace 708 of FIG. 7A. The table 770 shows a column showing maximum power (Pmax) at gain states GS0, GS1, GS2, GS3, GS4 and GS5; a column showing maximum power at the antenna (Pmax @ Ant), a column showing peak voltage at the input of the ADC (Vpeak @ ADC); and a column showing margin (in dB) for ADC saturation. Given that Δ=β−α=6 dB in this example, the Pmax @ Ant values for each gain stage is 6 dB lower in FIG. 7B than in FIG. 6B. Further, the ADC margin shown in the “Margin (dB)” column shows that for each gain state GS0 through GS5, there is ADC margin in addition to the ADC margin shown in FIG. 6B.

In an exemplary embodiment, the FBRx 315 undergoes a factory calibration process where the expected ADC input power (P_{ADC}_bar) is determined and a plurality of FBRx gain switch points are determined. Once the FBRx gain switch points are determined, a dynamic software enabled gain switch point adjustment process can occur. For example, the dynamic software enabled gain switch point adjustment can be executed by the data processor 210 of FIG. 2A, 2B or 2C using input provided by the coupler 305.

In an exemplary embodiment, the ADC input power (P_{ADC}), is measured and is subtracted from the expected ADC input power (P_{ADC}_bar), resulting in a delta (Δ).

The expected ADC input power (P_{ADC}_bar) can be determined according to:

P_{ADC}_bar=Pant−L_bar+G_bar, where Pant is antenna power, L_bar is nominal coupler loss (defined in software), and G_bar is the nominal FBRx gain (defined in software).

The measured ADC input power P_{ADC} can be determined by the processor 296 (FIG. 2A, 2B, 2C) from a signal provided by the coupler 305 (FIG. 3) according to:

P_{ADC}=P_{Ant}−(L_bar+α)+(G_bar+β)+γ, where α is excess coupling factor, β is excess FBRx gain, and Y is excess gain with temperature (from NV RAM).

The delta (Δ) can be determined according to:

$$Δ = {P}_{ADC} - {P}_{ADC} \_bar = β - α + Υ$$

In an exemplary embodiment, the gain switch points are adjusted according to Δ such that:

New (adjusted) switch point=Old switch point−Δ.

In an exemplary embodiment, the system and method for gain switch point adjustment reallocates excess SNR (or CNR) to the ADC saturation margin and reallocates ADC saturation margin to the CNR by changing the gain switch points of the gain element 311 to control the power at the input of the ADC 319. These computations for the gain switch point adjustment may be performed by the processor 296 in the data processor 210 (FIG. 2A, 2B, 2C) or another processor using input provided by the coupler 305 (FIG. 3). In this manner, the gain switch points of the gai element 311 may be adjusted to both avoid ADC saturation and maintain a minimum SNR for input to the ADC 319.

In some embodiments, a characteristic of the transmitter 330 (FIG. 3) in a transmit path may be adjusted based on the signal received at the FBRx 315 through a feedback path formed by the coupler 305 and the connection 307.

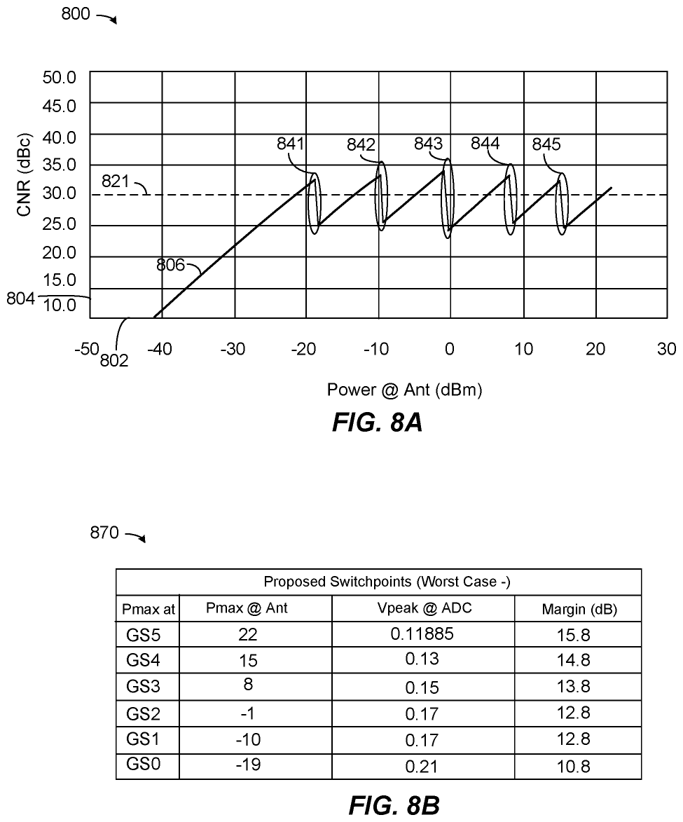

FIG. 8A is a graph 800 showing an exemplary minimum gain trace in a communication system that does not have the system and method for adjusting feedback receiver (FBRx) gain switch points. The graph 800 includes a horizontal axis 802 showing antenna power (Power @ Ant) in dBm, and a vertical axis 804 showing carrier-to-noise ratio (CNR) in dBc.

The graph 800 includes a trace 806 corresponding to a worst case minimum (−) gain condition. In an exemplary embodiment, the worst case minimum (−) gain condition assumes a 3 dB lower than nominal gain and a 3 dB higher than nominal coupling factor such that α is 3 dB; β is −3 dB and Δ=β−α=−6 dB.

The trace 806 includes gain switch points 841, 842, 843, 844 and 845. The trace 806 also shows CNR drop below the minimum of 30 dBc due to the low gain for each gain state. For example, each of the gain switch points 841, 842, 843, 844 and 845 indicate periods of CNR loss due to insufficient signal strength. The trace 806 shows a condition where the ADC 319 (FIG. 3) may receive a signal having lower than needed CNR due to insufficient signal strength.

FIG. 8B shows a table 870 showing proposed gain switch points corresponding to the worst case minimum (−) gain condition shown using trace 806 of FIG. 8A. The table 870 shows a column showing maximum power (Pmax) at gain states GS0, GS1, GS2, GS3, GS4 and GS5; a column showing maximum power at the antenna (Pmax @ Ant), a column showing peak voltage at the input of the ADC (Vpeak @ ADC); and a column showing margin (in dB) for ADC saturation. As shown in FIG. 8B, there is excess ADC margin for each gain state.

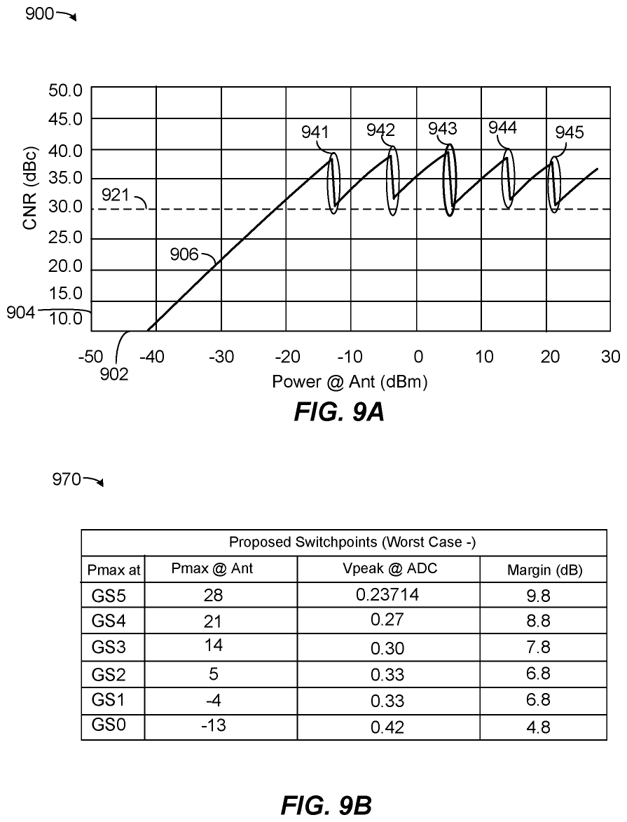

FIG. 9A is a graph 900 showing an exemplary minimum gain trace in a communication system having the system and method for adjusting feedback receiver (FBRx) gain switch points. The graph 900 includes a horizontal axis 902 showing antenna power (Power @ Ant) in dBm, and a vertical axis 904 showing carrier-to-noise ratio (CNR) in dBc.

The graph 900 includes a trace 906 corresponding to a worst case minimum (−) gain condition. The trace 906 includes gain switch points 941, 942, 943, 944 and 945. The trace 906 also shows that the switch points 941, 942, 943, 944 and 945 increase the CNR above the minimum of 30 dBc due to the switch points 941, 942, 943, 944 and 945 being adjusted per the above-mentioned process. For example, each of the gain switch points 941, 942, 943, 944 and 945 indicate periods of CNR above the minimum of 30 dBc. The trace 906 shows a condition where the ADC 319 (FIG. 3) may receive a signal having an acceptable CNR and where the ADC 319 (FIG. 3) is not saturated.

FIG. 9B shows a table 970 showing proposed gain switch points corresponding to the worst case minimum (−) gain condition shown using trace 906 of FIG. 9A. The table 970 shows a column showing maximum power (Pmax) at gain states GS0, GS1, GS2, GS3, GS4 and GS5; a column showing maximum power at the antenna (Pmax @ Ant), a column showing peak voltage at the input of the ADC (Vpeak @ ADC); and a column showing margin (in dB) for ADC saturation. Given that Δ=β−α=−6 dB in this example, the Pmax @ Ant values for each gain stage is 6 dB higher in FIG. 9B than in FIG. 8B, giving rise to additional CNR than that shown in FIG. 8B. Further, the ADC margin shown in the “Margin (dB)” column shows that for each gain state GS0 through GS5, there is less ADC margin than the ADC margin shown in FIG. 8B, but still sufficient ADC margin for each gain state.

In an exemplary embodiment, adjusting the gain switch points can improve the accuracy of the FBRx 315. For example, adjusting the gain switch points of the gain element 311 as described herein improves the accuracy of the power tracking provided by the FBRx 315, allows more accurate digital pre-distortion (DPD) coefficients to improve DPD operation in the transmitter, and also improves local oscillator feed through (LOFT) compensation for improving local oscillator leakage performance.

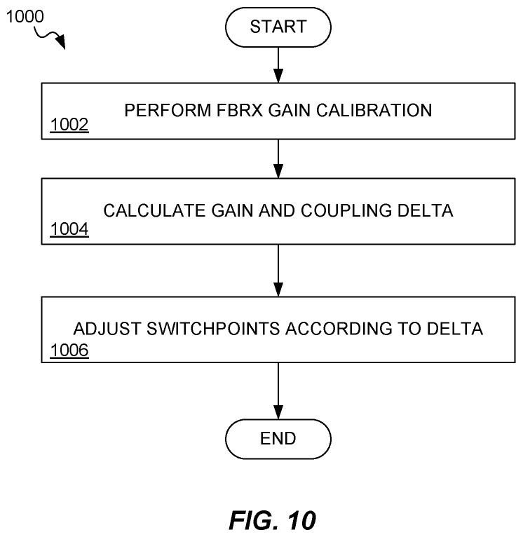

FIG. 10 is a flow chart 1000 describing an example of the operation of a method for adjusting FBRx gain switch points. The blocks in the method 1000 can be performed in or out of the order shown, and in some embodiments, can be performed at least in part in parallel.

In block 1002, the FBRx 315 undergoes a factory calibration process where the expected ADC input power (P_{ADC}_bar) is determined and a plurality of FBRx gain switch points are determined. For example, the expected ADC input power (P_{ADC}_bar) can be determined according to: P_{ADC}_bar=P_{Ant}-L_bar+G_bar, where P_{Ant} is antenna power, L_bar is nominal coupler loss (defined in software), and G_bar is the nominal FBRx gain (defined in software).

In block 1004, transmit signal gain and a coupling factor are calculated. For example, the measured ADC input power P_{ADC} can be determined according to: P_{ADC}=P_{Ant}−(L_bar+α)+ (G_bar+β)+γ, where α is excess coupling factor, β is excess FBRx gain, and Y is excess gain with temperature (from NV RAM). The delta (Δ) can be determined according to: Δ=P_{ADC}−P_{ADC}_bar=β−α+γ. For example, the transmit signal gain and the coupling factor can be determined by the processor 296 (FIG. 3) based on the signal provided to the gain element 311 by the coupler 305 in FIG. 3.

In block 1006, the ADC gain switch points are adjusted according to the delta (Δ). For example, the gain switch points are adjusted according to Δ such that: the new (adjusted) switch point=the old switch point−Δ. This determination can be made by the processor 296 using the memory 398.

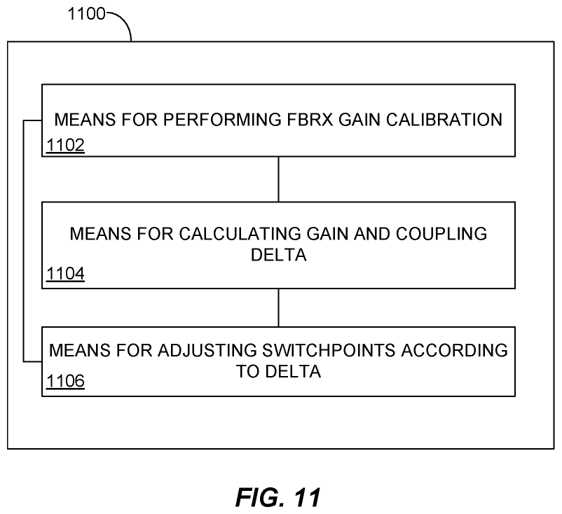

FIG. 11 is a functional block diagram of an apparatus 1100 for adjusting FBRx gain switch points. The apparatus 1100 comprises means 1102 for performing FBRx gain calibration. In certain embodiments, the means 1102 for performing FBRx gain calibration can be configured to perform one or more of the functions described in operation block 1002 of method 1000 (FIG. 10). In an exemplary embodiment, the means 1102 for performing FBRx gain calibration may comprise determining the expected ADC input power (P_{ADC}_bar) according to: P_{ADC}_bar=P_{Ant}-L_bar+G_bar, where P_{Ant} is antenna power, L_bar is nominal coupler loss (defined in software), and G_bar is the nominal FBRx gain (defined in software).

The apparatus 1100 may also comprise means 1104 for calculating transmit signal gain and a coupling factor. In certain embodiments, the means 1104 for calculating transmit signal gain and a coupling factor can be configured to perform one or more of the functions described in operation block 1004 of method 1000 (FIG. 10). In an exemplary embodiment, the means 1104 for calculating transmit signal gain and a coupling factor may comprise determining the measured ADC input power P_{ADC} according to: P_{ADC}=P_{Ant}−(L_bar+α)+(G_bar+β)+γ, where α is excess coupling factor, β is excess FBRx gain, and γ is excess gain with temperature (from NV RAM). The delta (Δ) can be determined according to: Δ=P_{ADC}−P_{ADC}_bar=β−α+γ.

The apparatus 1100 may also comprise means 1106 for adjusting the ADC gain switch points according to the delta (Δ). In certain embodiments, the means 1106 for adjusting the ADC gain switch points according to the delta (Δ) can be configured to perform one or more of the functions described in operation block 1006 of method 1000 (FIG. 10). In an exemplary embodiment, the means 1106 for adjusting the ADC gain switch points according to the delta (Δ) may comprise adjusting the gain switch points according to Δ such that: the new switch point=the old switch point−Δ.

Implementation examples are described in the following numbered clauses:

1. A system for adjusting feedback receiver gain, comprising: a power amplifier configured to generate a transmit signal; a feedback receiver configured to receive a portion of the transmit signal, the feedback receiver having a gain element and an analog-to-digital converter (ADC); and a processor and a memory operably coupled to the gain element; wherein the processor and memory are configured to select an adjusted gain switch point for the gain element based on a difference between a measured ADC input power and an expected ADC input power.

2. The system of clause 1, wherein the adjusted gain switch point is selected to be at a level that prevents ADC saturation.

3. The system of any of clauses 1 or 2, wherein the adjusted gain switch point is selected to be at a level that reallocates excess ADC input margin.

4. The system of any of clauses 1 through 3, wherein for a maximum gain condition the adjusted gain switch point is selected to reduce carrier-to-noise ratio (CNR) and increase ADC saturation margin.

5. The system of any of clauses 1 through 4, wherein for a minimum gain condition the adjusted gain switch point is selected to increase carrier-to-noise ratio (CNR) and reduce ADC saturation margin.

6. The system of any of clauses 1 through 5, wherein the measured ADC input power is a function of coupling factor, signal power and gain variation with temperature.

7. The system of any of clauses 1 through 6, wherein the adjusted gain switch point is based on a difference between a previous switch point and a difference between the measured ADC input power and the expected ADC input power.

8. The system any of clauses 1 through 7, wherein the processor and memory are configured to adjust the switch point for the gain element based on the difference between a measured ADC input power and an expected ADC input power.

9. A method for adjusting gain, comprising: determining an expected analog-to-digital converter (ADC) input power; measuring an actual ADC input power; determining a difference (Δ) between the actual ADC input power and the expected ADC input power; and adjusting a gain switch point based on the difference (Δ).

10. The method of clause 9, further comprising adjusting the gain switch point to prevent ADC saturation.

11. The method of any of clauses 9 through 10, further comprising adjusting the gain switch point to reallocate excess ADC input margin to carrier-to-noise (CNR).

12. The method of any of clauses 9 through 11, wherein for a maximum gain condition the gain switch point is selected to reduce excess carrier-to-noise (CNR) and increase ADC saturation margin.

13. The method of any of clauses 9 through 12, wherein for a minimum gain condition the gain switch point is selected to increase carrier-to-noise ratio (CNR) and reduce ADC saturation margin.

14. The method of any of clauses 9 through 13, wherein the measured actual ADC input power is a function of coupling factor, signal power and gain variation with temperature.

15. The method of any of clauses 9 through 14, wherein the gain switch point comprises the difference between an old switch point and the difference between the measured actual ADC input power and the expected ADC input power.

16. The method of any of clauses 9 through 15, wherein the gain switch point is associated with a gain element in a feedback receiver.

17. The method of any of clauses 9 through 16, further comprising: receiving a signal in a feedback path through a feedback receiver with a gain element; and controlling the gain element using the adjusted gain switch point.

18. The method of any of clauses 9 through 17, further comprising adjusting a characteristic of a transmit path based on the signal received through the feedback path.

19. A device for adjusting gain, comprising: means for determining an expected analog-to-digital converter (ADC) input power; means for measuring an actual ADC input power; means for determining a difference (Δ) between the actual ADC input power and the expected ADC input power; and means for adjusting a gain switch point based on the difference (Δ).

20. The device of clause 19, further comprising means for adjusting the gain switch point to prevent ADC saturation.

21. The device of any of clauses 19 through 20, further comprising means for adjusting the gain switch point to reallocate excess ADC input margin to carrier-to-noise ratio (CNR).

22. The device of any of clauses 19 through 21, further comprising means for selecting the gain switch point to reduce excess carrier-to-noise ratio (CNR) and increase ADC saturation margin.

23. The device of any of clauses 19 through 22, further comprising means for selecting the gain switch point to increase carrier-to-noise ratio (CNR) and reduce ADC saturation margin.

24. The device of any of clauses 19 through 23, wherein the measured actual ADC input power is a function of coupling factor, signal power and gain variation with temperature.

25. The device of any of clauses 19 through 24, wherein the gain switch point comprises the difference between an old switch point and the difference between the measured actual ADC input power and the expected ADC input power.

26. A communication device, comprising: a transmitter comprising a power amplifier configured to generate a transmit signal and a power coupler; a feedback receiver comprising a gain element and an analog-to-digital converter (ADC); the power coupler configured to provide a portion of the transmit signal to the feedback receiver; and a processor and a memory operably coupled to the gain element; wherein the processor and memory are configured to select gain switch points for the gain element based on a difference between a measured actual ADC input power of the ADC and an expected ADC input power of the ADC.

27. The communication device of clause 26, wherein the gain switch points that are selected are configured to prevent ADC saturation and to maintain a minimum carrier-to-noise ratio (CNR).

28. The communication device of any of clauses 26 through 27, wherein the selected gain switch points are configured to reallocate excess ADC input margin to carrier-to-noise ratio (CNR).

29. The communication device of any of clauses 26 through 28, wherein for a maximum gain condition the selected gain switch points are selected to reduce excess carrier-to-noise ratio (CNR) and increase ADC saturation margin.

30. The communication device of any of clauses 26 through 29, wherein for a minimum gain condition the selected gain switch points are selected to increase carrier-to-noise ratio (CNR) and reduce ADC saturation margin.

The circuit architecture described herein described herein may be implemented on one or more ICs, analog ICs, RFICs, mixed-signal ICs, ASICs, printed circuit boards (PCBs), electronic devices, etc. The circuit architecture described herein may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

An apparatus implementing the circuit described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

Although selected aspects have been illustrated and described in detail, it will be understood that various substitutions and alterations may be made therein without departing from the spirit and scope of the present invention, as defined by the following claims.

What is claimed is:

1. A system for adjusting feedback receiver gain, comprising:
a power amplifier configured to generate a transmit signal;
a feedback receiver configured to receive a portion of the transmit signal, the feedback receiver having a gain element and an analog-to-digital converter (ADC); and
a processor and a memory operably coupled to the gain element; wherein the processor and memory are configured to select an adjusted gain switch point for the gain element based on a difference between a measured ADC input power and an expected ADC input power.

2. The system of claim 1, wherein the adjusted gain switch point is selected to be at a level that prevents ADC saturation.

3. The system of claim 1, wherein the adjusted gain switch point is selected to be at a level that reallocates excess ADC input margin.

4. The system of claim 1, wherein for a maximum gain condition the adjusted gain switch point is selected to reduce carrier-to-noise ratio (CNR) and increase ADC saturation margin.

5. The system of claim 1, wherein for a minimum gain condition the adjusted gain switch point is selected to increase carrier-to-noise ratio (CNR) and reduce ADC saturation margin.

6. The system of claim 1, wherein the measured ADC input power is a function of coupling factor, signal power and gain variation with temperature.

7. The system of claim 1, wherein the adjusted gain switch point is based on a difference between a previous switch point and a difference between the measured ADC input power and the expected ADC input power.

8. The system of claim 1, wherein the processor and memory are configured to adjust the switch point for the gain element based on the difference between a measured ADC input power and an expected ADC input power.

9. A method for adjusting gain, comprising:
determining an expected analog-to-digital converter (ADC) input power;
measuring an actual ADC input power;
determining a difference (Δ) between the actual ADC input power and the expected ADC input power; and
adjusting a gain switch point based on the difference (Δ).

10. The method of claim 9, further comprising adjusting the gain switch point to prevent ADC saturation.

11. The method of claim 9, further comprising adjusting the gain switch point to reallocate excess ADC input margin to carrier-to-noise (CNR).

12. The method of claim 9, wherein for a maximum gain condition the gain switch point is selected to reduce excess carrier-to-noise (CNR) and increase ADC saturation margin.

13. The method of claim 9, wherein for a minimum gain condition the gain switch point is selected to increase carrier-to-noise ratio (CNR) and reduce ADC saturation margin.

14. The method of claim 9, wherein the measured actual ADC input power is a function of coupling factor, signal power and gain variation with temperature.

15. The method of claim 9, wherein the gain switch point comprises the difference between an old switch point and the difference between the measured actual ADC input power and the expected ADC input power.

16. The method of claim 9, wherein the gain switch point is associated with a gain element in a feedback receiver.

17. The method of claim 9, further comprising:
receiving a signal in a feedback path through a feedback receiver with a gain element; and
controlling the gain element using the adjusted gain switch point.

18. The method of claim 17, further comprising adjusting a characteristic of a transmit path based on the signal received through the feedback path.

19. A device for adjusting gain, comprising:
means for determining an expected analog-to-digital converter (ADC) input power;
means for measuring an actual ADC input power;
means for determining a difference (Δ) between the actual ADC input power and the expected ADC input power; and
means for adjusting a gain switch point based on the difference (Δ).

20. The device of claim 19, further comprising means for adjusting the gain switch point to prevent ADC saturation.

21. The device of claim 19, further comprising means for adjusting the gain switch point to reallocate excess ADC input margin to carrier-to-noise ratio (CNR).

22. The device of claim 19, further comprising means for selecting the gain switch point to reduce excess carrier-to-noise ratio (CNR) and increase ADC saturation margin.

23. The device of claim 19, further comprising means for selecting the gain switch point to increase carrier-to-noise ratio (CNR) and reduce ADC saturation margin.

24. The device of claim 19, wherein the measured actual ADC input power is a function of coupling factor, signal power and gain variation with temperature.

25. The device of claim 19, wherein the gain switch point comprises the difference between an old switch point and the difference between the measured actual ADC input power and the expected ADC input power.

26. A communication device, comprising:
a transmitter comprising a power amplifier configured to generate a transmit signal and a power coupler;
a feedback receiver comprising a gain element and an analog-to-digital converter (ADC);
the power coupler configured to provide a portion of the transmit signal to the feedback receiver; and
a processor and a memory operably coupled to the gain element; wherein the processor and memory are configured to select gain switch points for the gain element based on a difference between a measured actual ADC input power of the ADC and an expected ADC input power of the ADC.

27. The communication device of claim 26, wherein the gain switch points that are selected are configured to prevent ADC saturation and to maintain a minimum carrier-to-noise ratio (CNR).

28. The communication device of claim 26, wherein the selected gain switch points are configured to reallocate excess ADC input margin to carrier-to-noise ratio (CNR).

29. The communication device of claim 23, wherein for a maximum gain condition the selected gain switch points are selected to reduce excess carrier-to-noise ratio (CNR) and increase ADC saturation margin.

30. The communication device of claim 23, wherein for a minimum gain condition the selected gain switch points are selected to increase carrier-to-noise ratio (CNR) and reduce ADC saturation margin.
